(19) United States
(12) Patent Application Publication
(10) Pub. No.: US 2009/0133917 A1
(43) Pub. Date: May 28, 2009

(54) Multilayered Circuit Board for Connection to Bumps

(75) Inventors: Michio Horiuchi, Nagano-shi (JP); Yasue Tokutake, Nagano-shi (JP); Shigeaki Suganuma, Nagano-shi (JP); Naoyuki Koizumi, Nagano-shi (JP); Fumimasa Katagiri, Nagano-shi (JP)

Correspondence Address: IPUSA, P.L.L.C, 1054 31ST STREET, N.W., Suite 400, Washington, DC, 20007, US

(73) Assignee: SHINKO ELECTRIC INDUSTRIES CO., LTD.

(21) Appl. No.: 12/267,674

(22) Filed: Nov. 10, 2008

(30) Foreign Application Priority Data
Nov. 28, 2007 (JP) 2007-307857

(51) Int. Cl. H01R 12/02

(52) U.S. Cl. 174/261

(57) ABSTRACT

A circuit board on which an electronic device having bumps arranged in an array form is to be mounted includes a substrate having a multilayer structure that includes interconnect lines and insulating layers, and vias penetrating through one or more of the insulating layers and coupled to one or more of the interconnect lines, wherein the vias are arranged at positions that are the same as positions of the bumps to be connected on the substrate, and the vias project from a surface of the substrate so that upper-end portions of the vias are exposed from the surface of the substrate.

### BACKGROUND OF THE INVENTION

1. Field of the Invention

The disclosures herein generally relate to circuit boards, interconnect structures, and electronic devices, and particularly relate to a circuit board, an interconnect structure, and an electronic apparatus suitable for high circuit density.

2. Description of the Related Art

As the functionality and circuit density of electronic devices increase, the number of terminals of an electronic device (i.e., the number of flip-chip I/Os) increases, and, also, a bump pitch narrows. This gives rise to a need to provide high-density wiring for interconnection to bumps in the circuit substrate on which an electronic device is mounted. Such high-density wiring requires a more complex fabrication process, causing a drop in yield. In consideration of this, various studies have been conducted with respect to circuit boards having wiring structures suitable for an electronic device having high circuit density (see Japanese Patent Applications No. 2000-244106 and No. 11-068298, for example).

As indicators of density, the ratios “(bump pitch)/(pad diameter)” and “(wire width)/(wire interval)” may be taken into consideration. These ratios will be described below by referring to a circuit board 1 shown in FIG. 1.

The circuit board 1 shown in FIG. 1 has pads 3 formed on a surface 2a of a substrate 2. The bumps of an electronic device will be connected to these pads 3, to which interconnect lines 4 are connected. The diameter of each pad 3 is D, and the width of each interconnect line 4 is W. The bump pitch between two adjacent pads (e.g., the space between the pad 3a and the pad 3b) is denoted as P. Further, the space between two adjacent interconnect lines 4 is denoted as S.

The ratio “(bump pitch P)/(pad diameter D)” has exhibited changes over years such as (350 μm/200 μm)→(240 μm/110 μm)→(200 μm/90 μm). With respect to these ratios, the ratio “(wire width W)/(wire interval S)” required to provide two interconnect lines between the two adjacent pads is determined as (50 μm/50 μm)<(43 μm/43 μm) (36 μm/36 μm), respectively. Further, the ratio “(wire width W)/(wire interval S)” required to provide three interconnect lines between the two adjacent pads is determined as (30 μm/30 μm) D (26 μm/26 μm) (22 μm/22 μm), respectively. Based on this trend in the past, the bump pitch is expected to be narrowed to 100 μm or less in the near future.

If the pad diameter is set to 70 μm, for example, the ratio “(wire width W)/(wire interval S)” required to provide one interconnect line through a bump pitch of 100 μm is determined as (10 μm/10 μm). Further, the ratio “(wire width W)/(wire interval S)” required to provide two interconnect lines through a bump pitch of 100 μm is determined as (6 μm/6 μm).

The wire fabrication technology for a conventional circuit substrate (i.e., organic substrate) experiences a significant drop in yield as the wire width W becomes shorter than approximately 10 μm. It is almost impossible to use such technology for wire width shorter than 6 μm. As a method to provide fine interconnect wiring, wires may be formed by use of a sputtering technology on an inorganic substrate made of such material as ceramic or silicon. However, an increase in manufacturing cost is a problem.

Even if fine wires are properly formed, the wire resistance will increase due to the miniaturization. Further, the use of ceramic as substrate material gives rise to a problem in that parasitic capacitance associated with an increase in dielectric constant may create trouble.

Accordingly, there is a need for a circuit board, an interconnect structure, and an electronic apparatus that can attain high circuit density while achieving reduction in manufacturing cost and improvement in electrical characteristics.

### SUMMARY OF THE INVENTION

It is a general object of at least one embodiment of the present invention to provide a circuit board, an electronic device packaging structure, and an electronic apparatus that may substantially eliminate one or more problems caused by the limitations and disadvantages of the related art.

According to one aspect of implementation, a circuit board on which an electronic device having bumps arranged in an array form is to be mounted includes a substrate having a multilayer structure that includes interconnect lines and insulating layers, and vias penetrating through one or more of the insulating layers and coupled to one or more of the interconnect lines, wherein the vias are arranged at positions that are the same as positions of the bumps to be connected on the substrate, and the vias project from a surface of the substrate so that upper-end portions of the vias are exposed from the surface of the substrate.

According to another aspect of implementation, an electronic device packaging structure includes a circuit board having a multilayered substrate including interconnect lines and insulating layers and first vias penetrating through one or more of the insulating layers, wherein an electronic device having bumps arranged in an array form is to be mounted on the circuit board, wherein second vias are formed at positions that are the same as positions of the bumps to be connected on the substrate, such that one end of each of the second vias is coupled to one or more of the interconnect lines, and another end of each of the second vias is exposed on a surface of the substrate, and wherein the bumps are to be connected to upper-end portions of the second vias to mount the electronic device to the circuit board.

According to another aspect of implementation, an electronic apparatus includes an electronic device having bumps arranged in an array form, and a circuit board having a multilayered substrate and vias, the multilayered substrate including interconnect lines and insulating layers, the vias connected to one or more of the interconnect lines and penetrating through one or more of the insulating layers, and the electronic device being mounted on the circuit board, wherein the vias are arranged at positions that are the same as positions of the bumps connected on the substrate, and the vias project from a surface of the substrate so that upper-end portions of the vias are exposed from the surface of the substrate, and wherein the bumps of the electronic device are in direct contact with the upper-end portions of the vias to establish electrical coupling.

According to at least one embodiment of the present invention, vias are arranged at the same positions as positions where the bumps are connected on the substrate, and the upper-end portions of the vias are exposed on the surface of the substrate. With this arrangement, the bumps of the electronic device can be directly connected to the upper-end portions of the vias. There is thus no need to form interconnect lines on the surface of the substrate. The inner interconnect lines coupled to the vias can be used to provide electrical coupling for the bumps.

In such a structure, the inner interconnect lines can be formed on a plurality of layers by use of a multilayer structure substrate. The interconnect lines connected to the bumps through the vias can thus be distributed to the inner interconnect layers, which helps to broaden the pitch of the inner interconnect lines on each layer. This makes it possible to provide the terminals of the electronic device at high density and also to produce the circuit board at low cost while maintaining high electrical characteristics.

### BRIEF DESCRIPTION OF THE DRAWINGS

Other objects and further features of the present invention will be apparent from the following detailed description when read in conjunction with the accompanying drawings, in which:

FIG. 1 is a plan view of a related-art circuit board;

FIG. 2 is a plan view showing an enlarged view of a portion of a circuit board according to an embodiment of the present invention;

FIG. 3 is a cross-sectional view of the circuit board taken along a line A-A shown in FIG. 2;

FIG. 4 is a cross-sectional view of the circuit board taken along a line B-B shown in FIG. 2;

FIG. 5 is a plan view of a first insulating layer;

FIG. 6 is a plan view of a second insulating layer (as appear by removal of the first insulating layer);

FIG. 7 is a plan view of a third insulating layer (as appear by removal of the first and second insulating layers);

FIGS. 8A and 8B are drawings showing other examples of the arrangement of pad-connection vias;

FIGS. 9A through 9E are drawings for illustrating a first embodiment of a method of manufacturing a pad-connection via; and

FIGS. 10A through 10E are drawings for illustrating a second embodiment of a method of manufacturing a pad-connection via.

### DESCRIPTION OF THE PREFERRED EMBODIMENTS

In the following, embodiments for carrying out the present invention will be described by referring to the accompanying drawings.

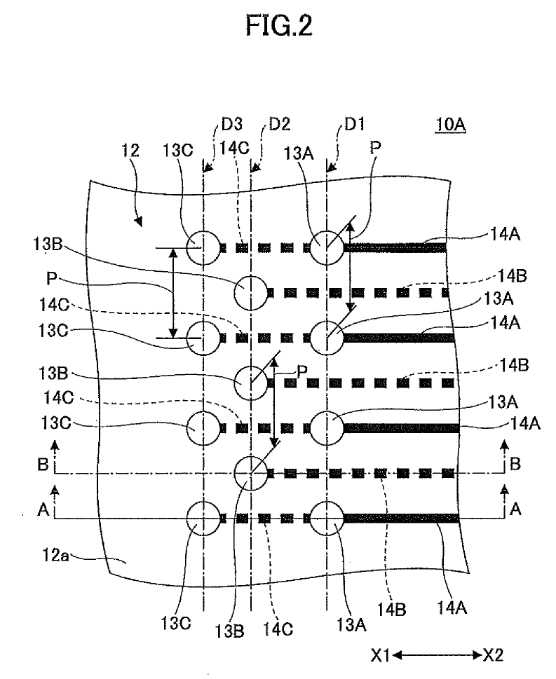

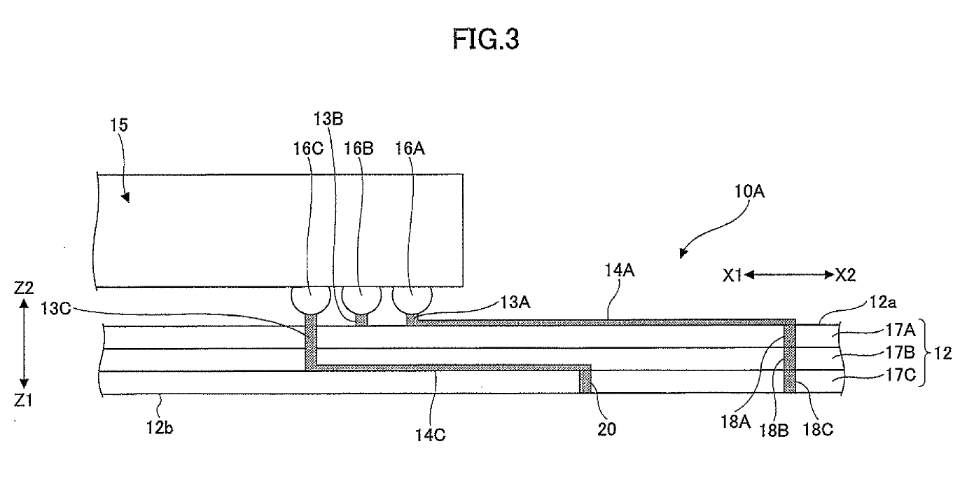

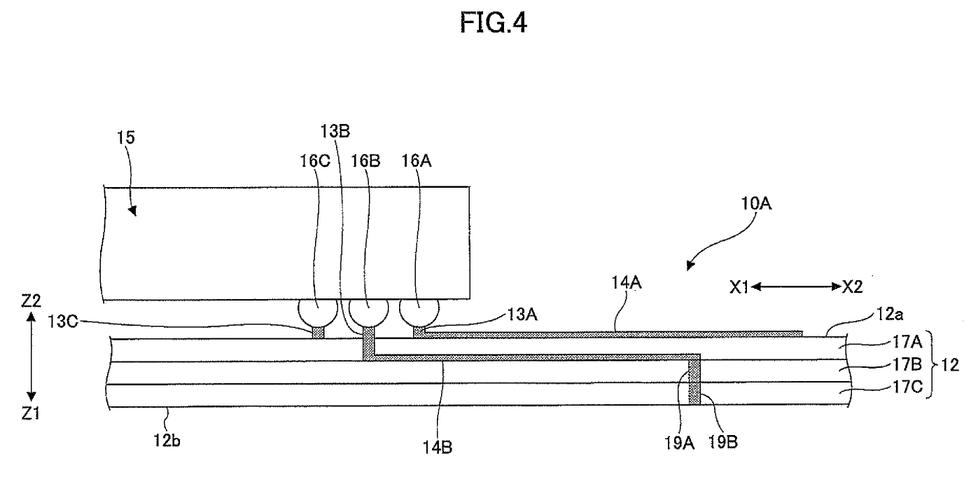

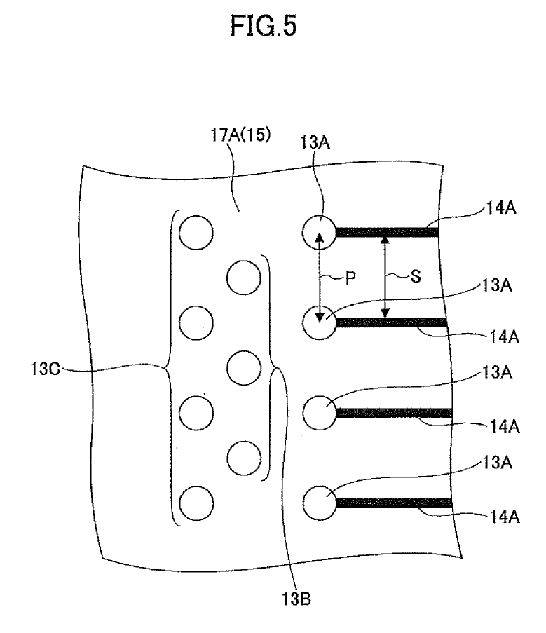

FIGS. 2 through 7 illustrate a circuit board 10A according to an embodiment of the present invention. FIG. 2 is a plan view showing an enlarged view of a portion of the circuit board 10A. FIG. 3 and FIG. 4 are drawings showing an interconnect structure and an electronic device when the electronic device is mounted on the circuit board 10A. FIGS. 5 through 7 are plan views of insulating layers constituting the circuit board 10A.

The circuit board 10A is mainly comprised of a substrate 12 and pad-connection vias 13 (which are individually shown as 13A, 13B, 13C in FIG. 2).

The substrate 12 has a multilayer structure in which insulating layers and interconnect lines are stacked one over another. The circuit board 10A according to the present embodiment has a three-layer structure in which insulating layers 17A through 17C and interconnect lines 14 are provided. In FIGS. 2-7, only outer-side interconnect lines 14A, center interconnect lines 14B, and inner-side interconnect lines 14C are shown as the interconnect lines 14.

The first through third insulating layers 17A through 17C are made of resin material such as epoxy-type resin or polyimide-type resin. The thickness of each of the insulating layers 17A through 17C may be 30 to 40 μm, for example. The interconnect lines 14 (i.e., outer-side interconnect lines 14A, center interconnect lines 14B, and inner-side interconnect lines 14C) are made of copper (Cu).

The pad-connection vias 13 have a lower-end portion in the thickness direction of the substrate 12 (i.e., an end on the Z1 side along an arrow Z1-Z2 as illustrated in FIGS. 3 and 4) coupled to the interconnect lines 14, and have an upper-end portion in the thickness direction of the substrate 12 (i.e., an end on the Z2 side along the arrow Z1-Z2 as illustrated in FIGS. 3 and 4) exposed from the surface 12a of the substrate 12. As will be described in detail, bumps 16 on an electronic device 15 are directly coupled to the exposed upper-end portions in a flip-chip manner. The pad-connection vias 13 penetrate through the insulating layers 17A through 17C at positions corresponding to the positions of the interconnect lines 14A through 14C to expose themselves from the surface 12a of the substrate 12.

The pad-connection vias 13 are made of Cu like the interconnect lines 14. The pad-connection vias 13 have a via structure filled with Cu, i.e., with no void space inside, by an electroplating process or via-fill electroplating.

As shown in FIG. 3 and FIG. 4, the electronic device 15 is mounted in a flip-chip manner on the circuit board 10A according to the present embodiment, thereby forming an electronic apparatus (semiconductor device). The electronic device 15 has the bumps 16 (which are individually shown as 16A, 16B, and 16C in FIGS. 3 and 4) arranged in an array form. The pad-connection vias 13 to be coupled to the bumps 16 are also arranged in an array form in one-to-one correspondence with the bumps 16.

In each of FIGS. 2-4, the X1 direction shown by an arrow X2 to X1 indicates an inner side of the electronic device 15, and the X2 direction shown by an arrow X1 to X2 indicates an outer side of the electronic device 15. In the following description, when there is a need to refer to the pad-connection vias 13 individually, they are referred to as outer-side vias 13A, center vias 13B, and inner-side vias 13C, depending on their positions. When there is a need to refer to the interconnect lines 14 individually, they are referred to as the outer-side interconnect lines 14A, the center interconnect lines 14B, and the inner-side interconnect lines 14C, depending on their positions. By the same token, the bumps 16 on the electronic device 15 are referred to as outer-side bumps 16A, center bumps 16B, and inner-side bumps 16C.

In the following, a description will be given with respect to an arrangement for the placement of the pad-connection vias 13. As was previously described, the circuit board 10A according to the present embodiment has high wiring and packaging density so that the electronic device 15 having a large number of bumps 16 can be mounted in a flip-chip manner. To this end, the pad-connection vias 13A through 13C to be coupled to the bumps 16A through 16C are placed at high density on the surface 12a of the substrate 12.

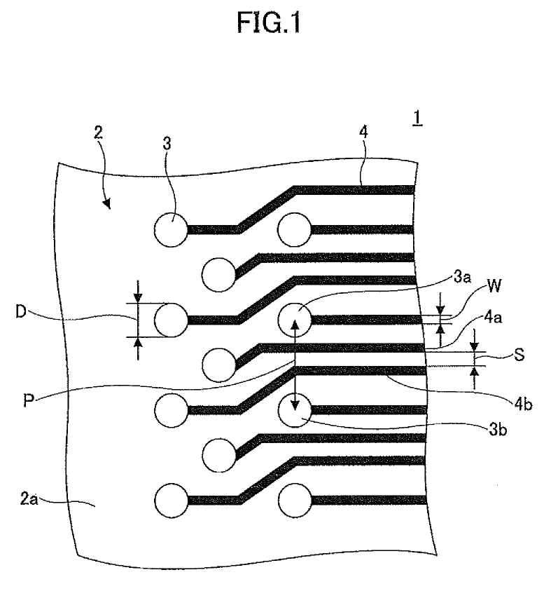

As was described in connection with FIG. 1, the related-art circuit board 1 has the pads 3 formed on the surface 2a of the substrate 2, and the interconnect lines 4 are employed to provide electrical couplings to the pads 3. In the circuit board 10A according to the present embodiment, on the other hand, no pads are used, and the bumps 16 (e.g., outer-side bumps 16A, center bumps 16B, and inner-side bumps 16C) are directly connected in a flip-chip manner to the upper-end portion of the pad-connection vias 13 (e.g., outer-side vias 13A, center vias 13B, and inner-side vias 13C) formed through the substrate 12.

The outer-side vias 13A are formed along a chain line D1 shown in FIG. 2, and can be regarded as pads formed on the surface 12a of the substrate 12. The center vias 13B are formed on the inner side along a chain line D2 shown in FIG. 2. The inner-side vias 13C are formed on the further inner side than the center vias 13B along a chain line D3 shown. A space (illustrated as an arrow P) between the adjacent vias 13A, 13B, and 13C is set to approximately 100 μm.

The outer-side vias 13A have an upper-end portion thereof (i.e., an end thereof on the Z2 side) projecting 10 to 20 μm, for example, from the surface 12a of the substrate 12. The lower-end portion of each outer-side via 13A (i.e., their end on the Z1 side) is coupled to the outer-side interconnect lines 14A formed on the surface 12a as shown in FIG. 3.

Each center via 13B also has an upper-end portion thereof (i.e., an end thereof on the Z2 side) projecting from the surface 12a of the substrate 12, and the length of such projection is set equal to that of the outer-side vias 13A. The lower-end portion of each center via 13B (i.e., their end on the Z1 side) is coupled to the center interconnect lines 14B formed on an upper face of the second insulating layer 17B as shown in FIG. 4.

Each inner-side via 13C also has an upper-end portion thereof (i.e., an end thereof on the Z2 side) projecting from the surface 12a of the substrate 12, and the length of such projection is set equal to those of the other vias 13A and 13B. The lower-end portion of each inner-side via 13C (i.e., their end on the Z1 side) is coupled to the inner-side interconnect lines 14C formed on an upper face of the third insulating layer 17C as shown in FIG. 3.

The length of the upper-end portion projections of the vias 13A through 13C from the surface 12a of the substrate 12 may be set to 20 μm. The diameter of the upper-end portion of each of the vias 13A through 13C may be set to 60 to 80 μm. From the viewpoint of high-density implementation, the diameter of an upper-end portion of each via 13A through 13C may preferably be set equal to the diameter of each bump 16A through 16C of the electronic device 15.

Further, an end of each of the outer-side interconnect lines 14A (i.e., an end on the X1 side in FIGS. 3 and 4) is coupled to a corresponding one of the outer-side vias 13A as previously described, and the other end thereof (i.e., an end on the X2 side in FIG. 3) is coupled to interlayer vias 18A through 18C. The interlayer vias 18A are formed to penetrate through the first insulating layer 17A. The interlayer vias 18B are formed to penetrate through the second insulating layer 17B. The interlayer vias 18C are formed to penetrate through the third insulating layer 17C. With this arrangement, electrical interconnections for the outer-side vias 13A are drawn out to a back surface 12b of the substrate 12 through the outer-side interconnect lines 14A and the interlayer vias 18A through 18C.

Further, an end of each of the center interconnect lines 14B (i.e., an end on the X1 side in FIG. 4) is coupled to a corresponding one of the center vias 13B as previously described, and the other end thereof (i.e., an end on the X2 side in FIG. 4) is coupled to interlayer vias 19A and 19B. The interlayer vias 19A are formed to penetrate through the second insulating layer 17B. The interlayer vias 19B are formed to penetrate through the third insulating layer 17C. With this arrangement, electrical interconnections for the center vias 13B are drawn out to the back surface 12b of the substrate 12 through the center interconnect lines 14B and the interlayer vias 19A and 19B.

Further, an end of each of the inner-side interconnect lines 14C (i.e., an end on the X1 side in FIG. 3) is coupled to a corresponding one of the inner-side vias 13C as previously described, and the other end thereof (i.e., an end on the X2 side in FIG. 3) is coupled to an interlayer via 20. Interlayer vias 20 are formed to penetrate through the third insulating layer 17C. With this arrangement, electrical interconnections for the inner-side vias 13C are drawn out to the back surface 12b of the substrate 12 through the inner-side interconnect lines 14C and the interlayer vias 20.

Attention is now focused on the space between the interconnect lines 14A through 14C formed on the upper faces of the insulating layers 17A through 17C, which constitute the substrate 12. FIG. 5 shows a plan view of the upper face of the first insulating layer 17A (i.e., the surface 12a of the substrate 12). As shown in FIG. 5, the upper face of the first insulating layer 17A has the outer-side vias 13A, center vias 13B, and inner-side vias 13C that are exposed to be coupled to the bumps 16.

In the circuit board 10A according to the present embodiment, the interconnect lines formed on the upper face of the first insulating layer 17A (i.e., the interconnect lines exposed on the upper surface of the first insulating layer 17A) only consist of the outer-side interconnect lines 14A. Even when the pitch P of the outer-side vias 13A is shorter than 100 μm, therefore, the distance S between two adjacent ones of the outer-side interconnect lines 14A can be set relatively wide. Specifically, the spacing distance S can be set approximately equal to the pitch P.

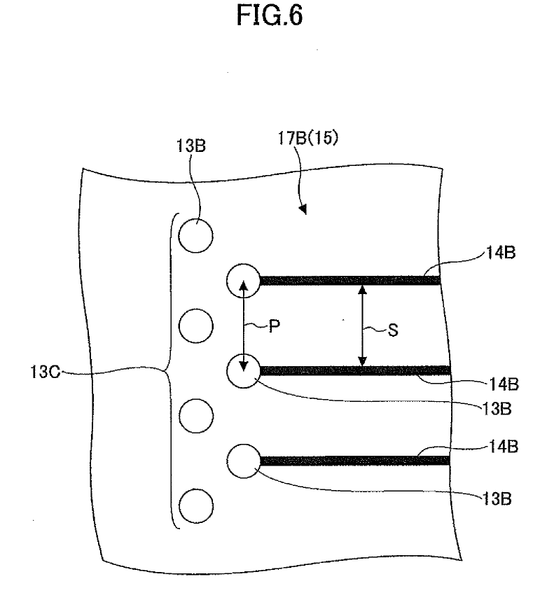

FIG. 6 is a drawing illustrating a plan view of the upper face of the second insulating layer 17B that could be exposed by removing the first insulating layer 17A from the circuit board 10A. As shown in FIG. 6, the upper face of the second insulating layer 17B has the center vias 13B and inner-side vias 13C that are coupled to the bumps 16.

In the circuit board 10A according to the present embodiment, the interconnect lines formed on the upper face of the second insulating layer 17B (i.e., the interconnect lines exposed on the upper surface of the second insulating layer 17B) only consist of the center interconnect lines 14B. On the upper face of the second insulating layer 17B, thus, the space S between two adjacent ones of the center interconnect lines 14B can be set wide.

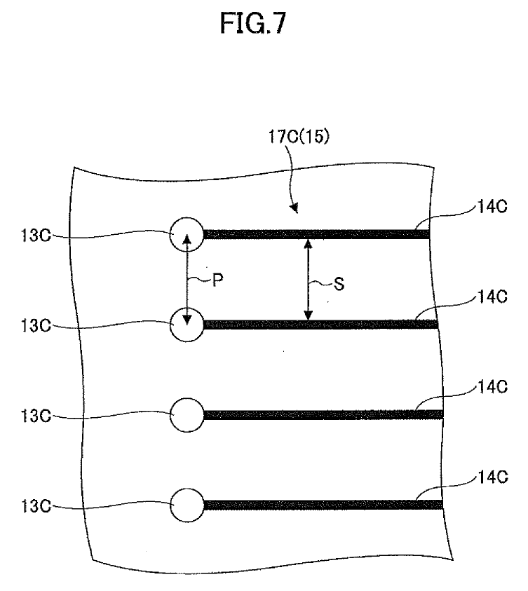

FIG. 7 is a drawing illustrating a plane view of the upper face of the third insulating layer 17C that could be exposed by removing the first and second insulating layers 17A and 17B from the circuit board 10A. As shown in FIG. 7, the upper face of the third insulating layer 17C has only the inner-side vias 13C that are coupled to the bumps 16.

In the circuit board 10A according to the present embodiment, the interconnect lines formed on the upper face of the third insulating layer 17C (i.e., the interconnect lines exposed on the upper surface of the third insulating layer 17C) only consist of the inner-side interconnect lines 14C. On the upper face of the third insulating layer 17C, thus, the interval S between two adjacent ones of the inner-side interconnect lines 14C can be set wide.

According to the circuit board 10A of the present embodiment described above, the provision of the pad-connection vias 13 (i.e., 13A through 13C) having Cu filling inside and projecting from the surface 12a of the substrate 12 at the positions where bumps are to be coupled makes it possible to directly connect the bumps 16 (i.e., 16A through 16C) of the electronic device 15 to the upper-end portions of the pad-connection vias 13 (i.e., 13A through 13C).

With such provision, there is no need to place all the interconnect lines on the surface 12a of the substrate 12. The interconnect lines 14 (i.e., 14A through 14C) coupled to the pad-connection vias 13 (i.e., 13A through 13C) can thus be distributed to various locations inside the substrate 12.

As a result, even when the pad-connection vias 13 (i.e., 13A through 13C) exposed on the surface 12a of the substrate 12 have a narrow pitch, the pitch of the interconnect lines 14 (i.e., 14A through 14C) formed on each of the insulating layers 17A through 17C can be set wider. This makes it possible to provide the terminals (i.e., bumps 16) of the electronic device 15 at a high density and also to produce the circuit board 10A at a low cost while maintaining high electrical characteristics.

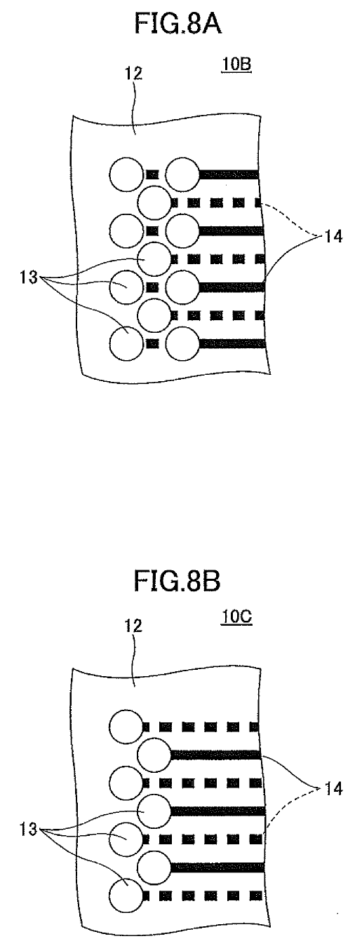

Further, the interconnect lines 14 connected to the pad-connection vias 13 are distributed to the surfaces of the insulating layers 17A through 17C. This provides latitude in the layout of the pad-connection vias 13 on the surface 12a of the substrate 12. As in circuit boards 10B and 10C shown in FIGS. 8A and 8B, respectively, any desired terminal layout is possible, which makes it possible to cope with various electronic devices 15 having different bump arrangement configurations.

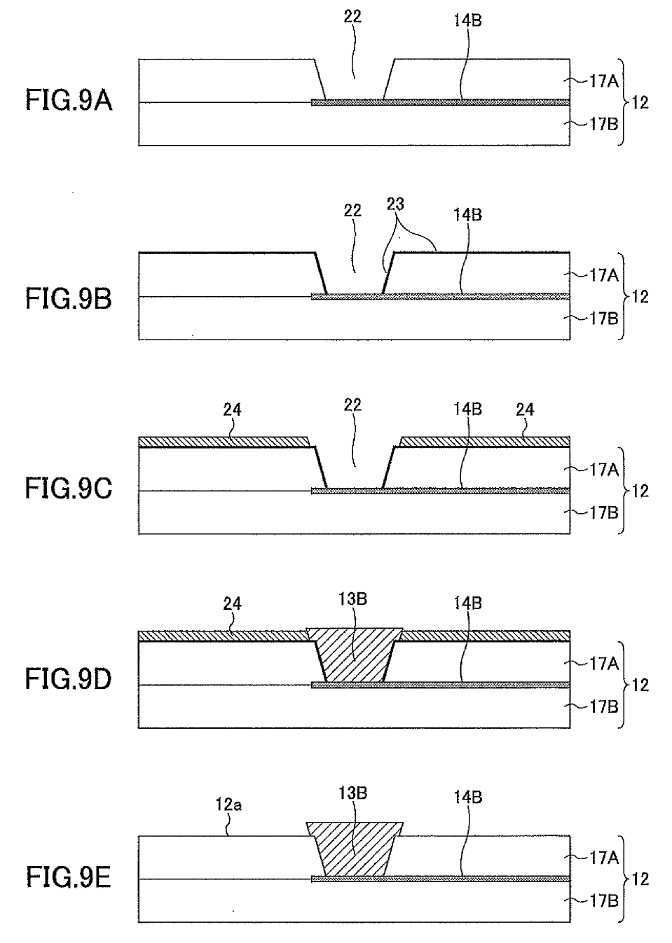

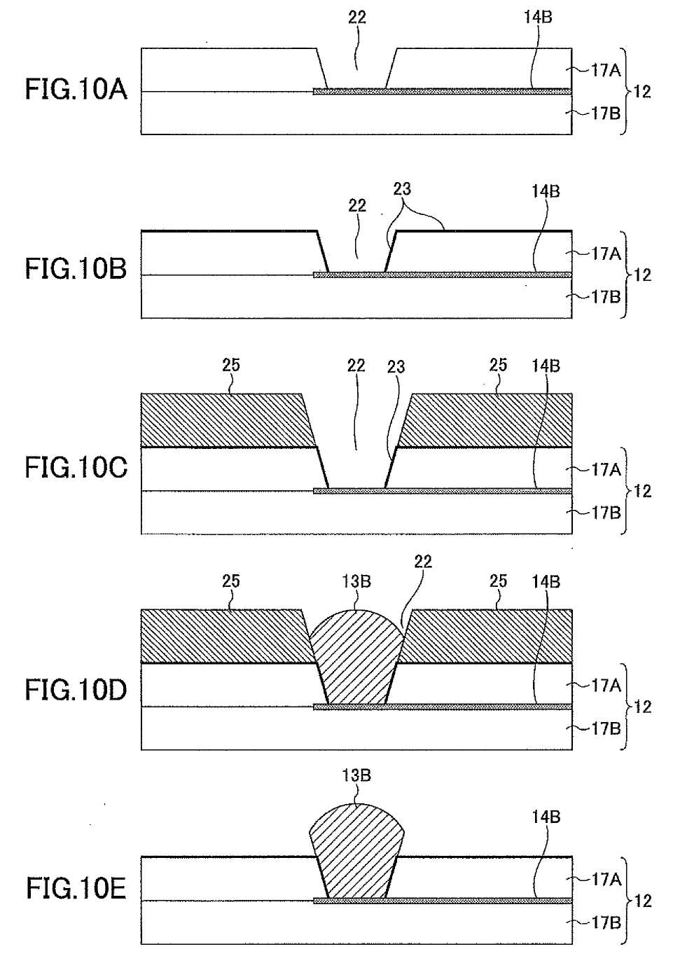

In the following, a method of forming the pad-connection vias 13 having the above-described configuration will be described by referring to FIG. 9 and FIG. 10. The following description will be directed to an example in which the center vias 13B are formed. It should be noted that a method of forming vias substantially the same as the described method can be used to form other pad-connection vias 13 (i.e., 13A and 13C).

In order to form a center via 13B, the first insulating layer 17A is formed over the second insulating layer 17B on which a center interconnect line 14B having a predetermined pattern is formed beforehand, thereby producing the substrate 12. Stacking of the first insulating layer 17A over the second insulating layer 17B can be performed by use of a well-known buildup method. The center interconnect line 14B may be formed by use of semi-additive method, for example. Instead of the semi-additive method, other interconnect-line forming methods may be employed such as a subtractive method or the like.

After the substrate 12 is produced, a via opening 22 is formed by a laser process at the position where a center via 13B is to be formed. The creation of the via opening 22 makes a portion of the center interconnect line 14B exposed. FIG. 9A shows the structure in which the via opening 22 is formed.

After this, a Cu seed layer 23 is formed by electroless plating or sputtering on the inner wall of the via opening 22 and the upper face of the first insulating layer 17A. FIG. 9B shows the structure after the Cu seed layer 23 is formed.

A resist 24 is then formed on the upper face of the first insulating layer 17A, except for the position of the via opening 22. The thickness of the resist 24 may preferably be 10 μm, for example. FIG. 9C shows the structure after the resist 24 is formed.

After the resist 24 is formed as described above, Cu electrolytic plating is performed by using as a power feeding layer the center interconnect line 14B and the Cu seed layer 23 electrically coupled to the center interconnect line 14B. In so doing, via-fill plating is performed in the present embodiment, This via-fill plating performs plating by adding to a plating bath an inhibitor for inhibiting the growth of plating and an accelerator for accelerating the growth of plating.

By use of this method, Cu is provided preferentially inside the via opening 22, thereby efficiently filling the via opening 22 with Cu. The center via 13B that is formed by the via-fill plating method has an upper-end portion having a flat surface as shown in FIG. 9D. This increases connectability with the bumps 16

After the center via 13B is formed as described above, the resist 24 and the seed layer 23 are removed. The center via 13B as shown in FIG. 9E is thus obtained that has its lower-end portion connected to the center interconnect line 14B and its upper-end portion projecting from the surface 12a of the substrate 12.

In the following, another method of forming the center vias 13B will be described by referring to FIG. 10. Processes shown in FIGS. 10A and 10B are the same as the processes illustrated in FIGS. 9A and 9B. In this embodiment, a resist 25 thicker than the resist 24 shown in FIG. 9C is formed as shown in FIG. 10C. The thickness of the resist 25 may preferably be 25 to 30 μm, for example.

In the electrolytic plating using the center interconnect line 14B and the seed layer 23 as a power feed layer, a normal plating method is used in this embodiment to plate Cu in the via opening 22, rather than using a via-fill plating method as used in the embodiment shown in FIGS. 9A through 9E. With this arrangement, the center via 13B will have a bulging shape like a bump projecting upwards as shown in FIG. 10D.

After the center via 13B is formed as described above, the resist 25 and the seed layer 23 are removed. The center via 13B as shown in FIG. 10E is thus obtained that has its lower-end portion connected to the center interconnect line 14B and its upper-end portion projecting from the surface 12a of the substrate 12.

The center via 13B having its lower-end portion connected to the center interconnect line 14B and its upper-end portion projecting from the surface 12a of the substrate 12 can be easily formed by use of a well-known technology such as buildup method, semi-additive method, via-fill plating method, or the like. Accordingly, the circuit board 10A configured to have the pad-connection vias 13 can be manufactured while suppressing an increase in production cost.

Further, the present invention is not limited to these embodiments, but various variations and modifications may be made without departing from the scope of the present invention.

The present application is based on Japanese priority application No. 2007-307857 filed on Nov. 28, 2007, with the Japanese Patent Office, the entire contents of which are hereby incorporated by reference.

What is claimed is:

1. A circuit board on which an electronic device having bumps arranged in an array form is to be mounted, comprising:
a substrate having a multilayer structure that includes interconnect lines and insulating layers; and
vias penetrating through one or more of the insulating layers and coupled to one or more of the interconnect lines,
wherein the vias are arranged at positions that are the same as positions of the bumps to be connected on the substrate, and the vias project from a surface of the substrate so that upper-end portions of the vias are exposed from the surface of the substrate.

2. The circuit board as claimed in claim 1, wherein the vias include a via hole and conductive material filling the via hole.

3. The circuit board as claimed in claim 1, wherein at least some of the vias penetrate through two or more of the insulating layers.

4. An electronic device packaging structure comprising a circuit board having a multilayered substrate including interconnect lines and insulating layers and first vias penetrating through one or more of the insulating layers,
wherein an electronic device having bumps arranged in an array form is to be mounted on the circuit board,
wherein second vias are formed at positions that are the same as positions of the bumps to be connected on the substrate, such that one end of each of the second vias is coupled to one or more of the interconnect lines, and another end of each of the second vias is exposed on a surface of the substrate, and
wherein the bumps are to be connected to upper-end portions of the second vias to mount the electronic device to the circuit board.

5. The electronic device packaging structure as claimed in claim 4, wherein a diameter of each one of the second vias is set equal to a diameter of the bumps.

6. An electronic apparatus, comprising:
an electronic device having bumps arranged in an array form; and
a circuit board having a multilayered substrate and vias, the multilayered substrate including interconnect lines and insulating layers, the vias connected to one or more of the interconnect lines and penetrating through one or more of the insulating layers, and the electronic device being mounted on the circuit board,
wherein the vias are arranged at positions that are the same as positions of the bumps connected on the substrate, and the vias project from a surface of the substrate so that upper-end portions of the vias are exposed from the surface of the substrate, and
wherein the bumps of the electronic device are in direct contact with the upper-end portions of the vias to establish electrical coupling.

7. A circuit board on which an electronic device having bumps arranged in a predetermined array pattern is to be mounted, comprising:
a substrate including two or more insulating layers and interconnect lines, which includes first interconnect lines disposed on a surface of the substrate and second interconnect lines disposed between the insulating layers;
pads formed on the surface of the substrate, each of the pads coupled to one of the first interconnect lines and having an upper end portion elevated from the surface of the substrate;
vias each having a via hole penetrating through one or more of the insulating layers and conductive core filling the via hole, the conductive core having a lower end portion coupled to one of the second interconnect lines and an upper end portion projecting from the surface of the substrate,
wherein the pads and vias are arranged in said predetermined array pattern to bring the upper ends of the pads and the upper end of the conductive core in direct contact with the bumps.
